(19) United States
(12) Patent Application Publication
(10) Pub. No.: US 2011/0007910 A1
(43) Pub. Date: Jan. 13, 2011

(54) VOLUME CONTROL DEVICE AND METHOD FOR USING THE SAME

(75) Inventors: Hsing-Yuan Hsieh, Shindian (TW); Jing Zhang, Shenzhen City (CN)

Correspondence Address: Altis Law Group, Inc.;ATTN: Steven Reiss, 288 SOUTH MAYO AVENUE, CITY OF INDUSTRY, CA, 91789, US

(73) Assignees: SHENZHEN FUTAIHONG PRECISION INDUSTRY CO., LTD., ShenZhen City (CN); FIH (HONG KONG) LIMITED, Kowloon (HK)

(21) Appl. No.: 12/783,029

(22) Filed: May 19, 2010

(30) Foreign Application Priority Data
Jul. 13, 2009 (CN) 200910304305.0

(51) Int. Cl. H03G 3/20

(52) U.S. Cl. 381/77; 381/107

(57) ABSTRACT

A volume control device used in a portable electronic device includes an input unit, an adjustment unit connected to the input unit; and an output unit connected to the adjustment unit. The input unit receives transmitted communication signals or audio signals of audio files played by the portable electronic device and transmits the audio signals to the adjustment unit, the adjustment unit automatically adjusts the voltages of the audio signals to a predetermined adjusted voltage range and transmits the adjusted audio signals to the output unit, and the output unit automatically adjusts the voltage of the audio signals transmitted from the adjustment unit to a selected broadcast voltage range and broadcasts the audio signals.

### BACKGROUND

1. Technical Field

The present disclosure relates to volume control, and particularly to an automatic volume control device for portable electronic devices and a method for using the same.

2. Description of Related Art

When portable electronic devices are used in speech communications or to play audio files, the volume of playing speech signals or audio files often needs to be adjusted. Therefore, most portable electronic devices have volume control buttons mounted thereon. However, these volume control buttons are generally manually operated, which may complicate operations of the portable electronic devices.

Therefore, there is room for improvement within the art.

### BRIEF DESCRIPTION OF THE DRAWINGS

Many aspects of the present disclosure can be better understood with reference to the following drawings. The components in the various drawings are not necessarily drawn to scale, the emphasis instead being placed upon clearly illustrating the principles of the present disclosure. Moreover, in the drawings, like reference numerals designate corresponding parts throughout the figures.

FIG. 1 is a block diagram of a volume control device for portable electronic devices, according to an exemplary embodiment.

FIG. 2 is a flowchart of a volume control method used in portable electronic devices, according to an exemplary embodiment.

### DETAILED DESCRIPTION

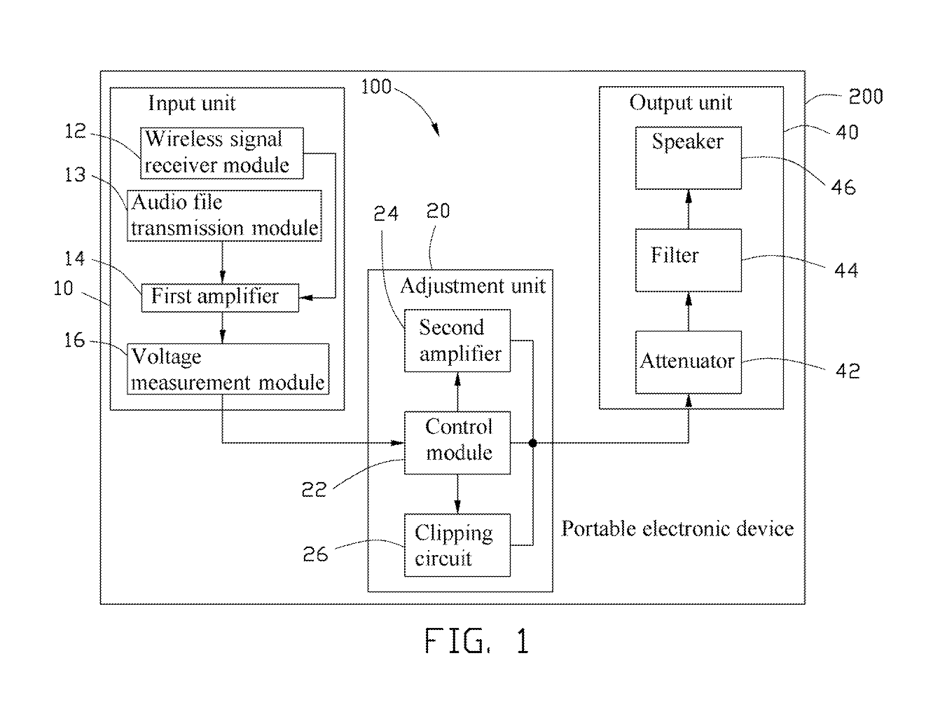

FIG. 1 shows a volume control device 100, according to an exemplary embodiment. The volume control device 100 can be installed in a portable electronic device 200, such as a mobile phone, an MP3 player, a CD player, or other device. As is known in the art, a preferable volume range of audio signals played by portable electronic devices is about 50 dB-70 dB. Correspondingly, broadcast voltage range of audio signals having a volume of about 50 dB-70 dB is about 5 mV-50 mV. Accordingly, the present volume control device 100 is configured to automatically adjust the voltages of the audio signals (including speech communication signals used in wireless communications and audio signals of audio files) broadcast by the portable electronic device 200 to about 5 mV-50 mV.

The volume control device 100 includes an input unit 10, an adjustment unit 20, and an output unit 40. The input unit 10, the adjustment unit 20, and the output unit 40 are electrically connected in series.

The input unit 10 includes an wireless signal receiver module 12, an audio file transmission module 13, a first amplifier 14, and a voltage measurement module 16. The wireless signal receiver module 12 and the audio file transmission module 13 are both electrically connected to the first amplifier 14. The first amplifier 14 is electrically connected to the voltage measurement module 16.

The wireless signal receiver module 12 can be a conventional wireless communication signal receiving device of the portable electronic device 200. When the portable electronic device 200 is used in wireless speech communication, the wireless signal receiver module 12 receives the audio signals sent to the portable electronic device 200 and transmits the audio signals to the first amplifier 14. The audio file transmission module 13 is electrically connected to a conventional audio player (not shown) of the portable electronic device 200. The audio file transmission module 13 can receive the audio signals of audio files played by the portable electronic device 200 and transmit the audio signals to the first amplifier 14. The first amplifier 14 can amplify the audio signals transmitted from the wireless signal receiver module 12 or the audio file transmission module 13 to increase the voltages of the audio signals by predetermined increments, such that the voltages of the audio signals can be adjusted more precisely, and then transmit the amplified audio signals to the voltage measurement module 16. In the present disclosure, the first amplifier 14 is configured to increase the voltages of the audio signals transmitted from the wireless signal receiver module 12 or the audio file transmission module 13 by 50 times. The amplified audio signals can be transmitted from the input unit 10 to the adjustment unit 20 through the voltage measurement module 16. When receiving the amplified audio signals, the voltage measurement module 16 detects the voltages of the amplified audio signals and sends the results to the adjustment unit 20.

The adjustment unit 20 includes a control module 22, a second amplifier 24, and a clipping circuit 26. The control module 22 is electrically connected to the voltage measurement module 16, the second amplifier 24, and the clipping circuit 26. The control module 22, the second amplifier 24, and the clipping circuit 26 are all electrically connected to the output unit 40. The control module 22 can be a conventional processor, such as a central processing unit (CPU) (not shown) of the portable electronic device 200. In use, the control module 22 receives the amplified audio signals transmitted from the voltage measurement module 16, and synchronously receives the voltage values of the amplified audio signals detected by the voltage measurement module 16. According to the voltage values of the amplified audio signals, the control module 22 can directly transmit the amplified audio signals to the output unit 40, or selectively transmit the amplified audio signals to the second amplifier 24 or the clipping circuit 26.

Particularly, the adjustment unit 20 adjusts the voltages of the amplified audio signals to a predetermined adjusted voltage range. For example, the adjusted voltage range can be 50 times the selected broadcast voltage range (about 5 mV-50 mV), which is, about 0.25V-2.5V.

Accordingly, if the voltage value of an amplified audio signal is in the adjusted voltage range (0.25V-2.5V), the control module 22 directly transmits the amplified audio signal to the output unit 40. If the voltage value of an amplified audio signal is lower than the lower limit of the adjusted voltage range, for example, less than 0.25V, the control module 22 transmits the amplified audio signal to the second amplifier 24. The second amplifier 24 further amplifies the audio signal to further increase the voltage of the audio signal by predetermined increments, such that the voltage of the audio signal is adjusted to the adjusted voltage range (0.25V-2.5V), and thus transmits the adjusted audio signal to the output unit 40. In the present disclosure, the second amplifier 24 is configured to further increase the voltages of the audio signals amplified by the first amplifier 14 by 10 times, such that most audio signals having voltages lower than the lower limit of the adjusted voltage range but close to the adjusted voltage range are adjusted to have voltages in adjusted voltage range. If the voltage value of an amplified audio signal is higher than the upper limit of the adjusted voltage range, for example, higher than 2.5V, the control module 22 transmits the amplified audio signal to the clipping circuit 26. The clipping circuit 26 limits the voltage of the audio signal to adjust the voltage of the audio signal to the adjusted voltage range (0.25V-2.5V), and thus transmits the adjusted audio signal to the output unit 40.

The output unit 40 includes an attenuator 42, a filter 44, and a speaker 46. The attenuator 42, the filter 44, and the speaker 46 are electronically connected in series. The control module 22, the second amplifier 24, and the clipping circuit 26 are all electrically connected to the attenuator 42. The attenuator 42 is configured to attenuate the audio signals transmitted from the adjustment unit 20 to reduce the voltages of the audio signals by predetermined increments, and the attenuating times of the attenuator equal the amplifying times of the first amplifier 14. Thus, the voltages of the attenuated audio signals are adjusted to the selected broadcast voltage range, that is 5 mV-50 mV. The filter 44 filters noise in the attenuated audio signals, and the speaker 46 broadcasts the filtered audio signals. Correspondingly, the volume of the broadcast audio signals is in the range of about 50 dB-70 dB.

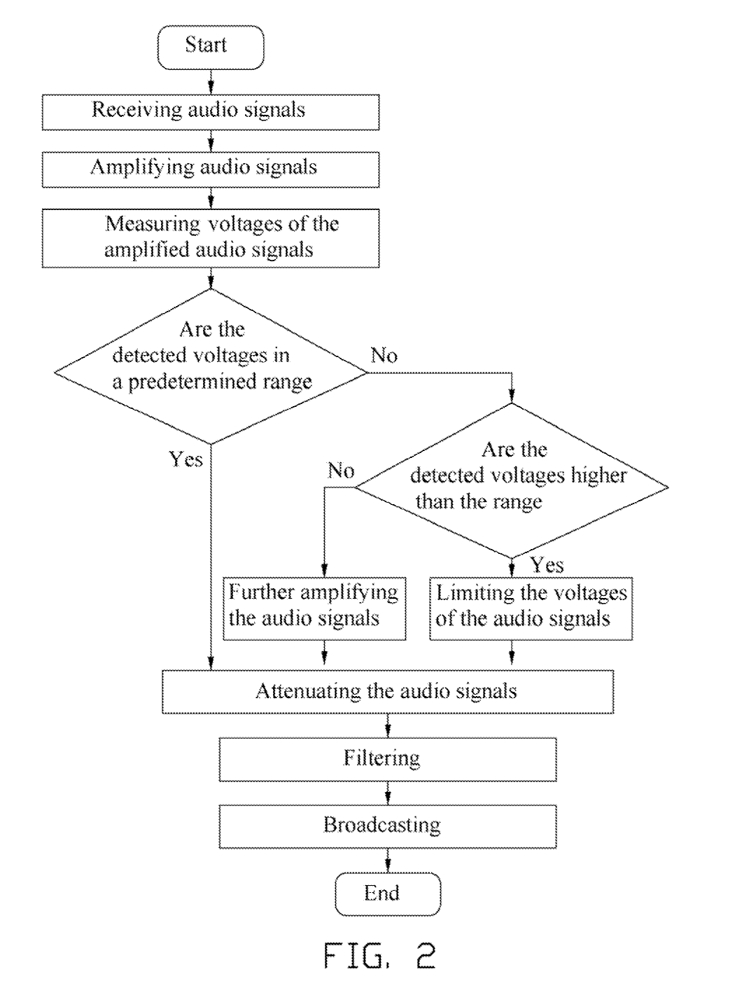

Also referring to FIG. 2, a volume control method used in portable electronic devices, according to an exemplary embodiment, is provided. The method utilizes the volume control device 100 installed in the portable electronic device 200 as follows.

First, if the portable electronic device 200 is providing wireless speech communication, the wireless signal receiver module 12 receives transmitted communication signals and forwards the signals to the first amplifier 14. If the portable electronic device 200 is providing playback of audio files, the audio file transmission module 13 receives transmitted audio files and forwards the signals to the first amplifier 14. In either case, the first amplifier 14 amplifies the received signals to increase the voltages thereof by predetermined increments, such as the aforementioned 50 times, and transmits the amplified audio signals to the adjustment unit 20 through the voltage measurement module 16. When receiving the amplified audio signals, the voltage measurement module 16 measures the voltages of the amplified audio signals and sends the results to the adjustment unit 20.

The control module 22 receives the amplified audio signals transmitted from the voltage measurement module 16, and synchronously receives the voltage values of the amplified audio signals measured by the voltage measurement module 16. If the voltage value of an amplified audio signal is within a predetermined adjusted voltage range, such as the aforementioned 0.25V-2.5V, the control module 22 directly transmits the amplified audio signal to the output unit 40. If the voltage value of an amplified audio signal is below the lower limit of the adjusted voltage range, the control module 22 transmits the amplified audio signal to the second amplifier 24. The second amplifier 24 further amplifies the audio signal to further increase the voltage of the audio signal by predetermined increments, such as the aforementioned 10 times, such that the voltage of the audio signal is adjusted to the adjusted voltage range, and thus transmits the adjusted audio signal to the output unit 40. If the voltage value of an amplified audio signal is higher than the upper limit of the adjusted voltage range, the control module 22 transmits the amplified audio signal to the clipping circuit 26. The clipping circuit 26 limits the voltage of the audio signal to within the adjusted voltage range, and transmits the adjusted audio signal to the output unit 40.

The attenuator 42 attenuates the audio signals transmitted from the adjustment unit 20 to reduce the voltages of the audio signals by predetermined increments that equal the amplifying times of the first amplifier 14. Thus, the voltages of the attenuated audio signals are adjusted to a selected broadcast voltage range, such as the aforementioned 5 mV-50 mV. The filter 44 filters noise in the attenuated audio signals, and the speaker 46 broadcasts the filtered audio signals. Corresponding to the selected broadcast voltage range of 5 mV-50 mV, the volume of the broadcast audio signals is in the range of about 50 dB-70 dB.

In the present disclosure, the volume control device 100 can automatically adjust the volume of communication signals or audio files on the portable electronic device 200 to predetermined preferred volume ranges, thereby simplifying operations of the portable electronic device 200. Relative parameters of the volume control device 100, such as the adjusted voltage range, the selected broadcast voltage range, the amplifying times of the first amplifier 14 and the second amplifier 24, the attenuating times of the attenuator 42, and the voltage limit of the clipping circuit 26, can be changed.

It is to be further understood that even though numerous characteristics and advantages of the present embodiments have been set forth in the foregoing description, together with details of structures and functions of various embodiments, the disclosure is illustrative only, and changes may be made in detail, especially in matters of shape, size, and arrangement of parts within the principles of the present invention to the full extent indicated by the broad general meaning of the terms in which the appended claims are expressed.

What is claimed is:

1. A volume control device for a portable electronic device, comprising:
an input unit;
an adjustment unit connected to the input unit; and
an output unit connected to the adjustment unit; wherein the input unit receives transmitted communication signals or audio signals of audio files and transmits the received audio signals to the adjustment unit, the adjustment unit adjusts the voltages of the audio signals to within a predetermined adjusted voltage range and transmits the adjusted audio signals to the output unit, the output unit then adjusts the voltage of the audio signals transmitted from the adjustment unit to within a selected broadcast voltage range and broadcasts the audio signals.

2. The volume control device as claimed in claim 1, wherein the input unit includes a voltage measurement module connected to the adjustment unit, the audio signals transmitted from the input unit to the adjustment unit through the voltage measurement module, the voltage measurement module measuring the voltages of the audio signals transmitted from the input unit to the adjustment unit and transmitting the results to the adjustment unit.

3. The volume control device as claimed in claim 2, wherein the input unit further includes a first amplifier connected to the voltage measurement module, the first amplifier amplifying the audio signals received by the input unit to increase the voltages of the received audio signals by predetermined increments and transmitting the amplified audio signals to the voltage measurement module.

4. The volume control device as claimed in claim 3, wherein the input unit further includes a wireless signal receiver module and an audio file transmission module both connected to the amplifier, the wireless signal receiver module receiving transmitted audio signals and transmitting the audio signals to the first amplifier, and the audio file transmission module receiving transmitted audio signals of audio files played by the portable electronic device and transmitting the audio signals to the first amplifier.

5. The volume detecting device as claimed in claim 3, wherein the adjustment unit includes a control module, a second amplifier, and a clipping circuit, the control module connected to the voltage measurement module, the second amplifier and the clipping circuit both connected to the control module, and the control module, the second amplifier, and the clipping circuit all connected to the output unit; wherein the control module receives the audio signals transmitted from the voltage measurement module and the voltage values of the audio signals measured by the voltage measurement module, and directly transmits the audio signals to the output unit or selectively transmits the audio signals to the second amplifier or the clipping circuit according to the voltage values of the audio signals.

6. The volume detecting device as claimed in claim 5, wherein when the voltage of the audio signals is within a predetermined adjusted voltage range, the control module directly transmits the audio signals to the output unit; when the voltage of the audio signals fall below the lower limit of the adjusted voltage range, the control module transmits the audio signals to the second amplifier, and the second amplifier further amplifies the audio signals and transmits the further amplified audio signals to the output unit; and when the voltage value of the audio signals exceed the upper limit of the adjusted voltage range, the control module transmits the audio signals to the clipping circuit, and the clipping circuit limits the voltage of the audio signals to the adjusting voltage range and transmits the adjusted audio signals to the output unit.

7. The volume control device as claimed in claim 3, wherein the output unit includes an attenuator, a filter and a speaker connected in series, the attenuator connected to the adjustment unit and attenuating the audio signals transmitted from the adjustment unit to reduce the voltages of the audio signals by predetermined increments, the filter filtering noise in the attenuated audio signals, and the speaker broadcasting the filtered audio signals.

8. The volume control device as claimed in claim 7, wherein the attenuating times of the attenuator equal the amplifying times of the first amplifier.

9. A volume control method used in portable electronic devices, comprising:
receiving transmitted communication signals or audio signals of audio files played by the portable electronic device;
amplifying the received audio signals to increase the voltages of the audio signals by predetermined increments;
adjusting the voltages of the amplified audio signals to a predetermined adjusted voltage range;
attenuating the amplified audio signals to reduce the voltages of the audio signals by predetermined increments, thereby adjusting the voltages of the audio signals to a selected broadcast voltage range; and
broadcasting the audio signals.

10. The method as claimed in claim 9, wherein when the voltage of the audio signals is within the adjusting voltage range, the audio signals are directly attenuating; when the voltage of the audio signals fall below the lower limit of the adjusted voltage range, the audio signals are further amplified; and when the voltage value of the audio signals exceed the upper limit of the adjusted voltage range, the voltages of the audio signals are limited.

11. The method as claimed in claim 9, wherein the attenuating times equal the amplifying times.
